(19) United States
(12) Patent Application Publication
(10) Pub. No.: US 2022/0179007 A1
(43) Pub. Date: Jun. 9, 2022

(54) METHOD OF ESTIMATING STATE OF CHARGE OF SECONDARY BATTERY, SYSTEM FOR ESTIMATING STATE OF CHARGE OF SECONDARY BATTERY, AND METHOD OF DETECTING ANOMALY OF SECONDARY BATTERY

(71) Applicant: SEMICONDUCTOR ENERGY LABORATORY CO., LTD., Kanagawa (JP)

(72) Inventors: Akihiro CHIDA, Kanagawa (JP); Mayumi MIKAMI, Kanagawa (JP)

(21) Appl. No.: 17/441,324

(22) PCT Filed: Mar. 23, 2020
(86) PCT No.: PCT/IB2020/052666

§ 371 Date: Sep. 21, 2021

(30) Foreign Application Priority Data
Apr. 2, 2019 (JP) 2019-070555

(51) Int. Cl. G01R 31/388; H01M 10/48; G01R 31/367; H02J 7/00

(52) U.S. Cl. CPC G01R 31/388; H01M 10/48; H01M 2220/20; H02J 7/0048; G01R 31/367

(57) ABSTRACT

A method of estimating the state of charge of a secondary battery that has high estimation accuracy even when degradation of the secondary battery progresses is provided. Furthermore, a capacity measurement system of a secondary battery that estimates an SOC with high estimation accuracy in a short time at low cost is provided. When the capacity of a secondary battery can be estimated with high accuracy, an anomaly can also be detected in accordance with the value. A novel method of detecting an anomaly of a secondary battery is provided. In the CCCV charging method, the CC time and the CV time are used as learning parameters to construct a learning model. With this learning model, an estimated capacity value with high accuracy can be obtained with use of two data, which are the CC time and the CV time, or three data, which are the CC time, the CV time, and a charge inception voltage value as the minimum input data.

### TECHNICAL FIELD

One embodiment of the present invention relates to an object, a method, or a manufacturing method. Alternatively, the present invention relates to a process, a machine, manufacture, or a composition (composition of matter). One embodiment of the present invention relates to a semiconductor device, a display device, a light-emitting device, a power storage device, a lighting device, an electronic device, or a manufacturing method thereof. In addition, one embodiment of the present invention relates to a method of estimating the state of charge of a power storage device, a system for estimating the state of charge of a power storage device, and a method of detecting anomaly of a power storage device. In particular, one embodiment of the present invention relates to a system for estimating the state of charge of a power storage device and a system for detecting an anomaly of a power storage device.

Note that in this specification, a power storage device refers to every element and device having a function of storing power. For example, the power storage device includes a storage battery (also referred to as secondary battery) such as a lithium-ion secondary battery, a lithium-ion capacitor, a nickel hydrogen battery, an all-solid-state battery, and an electric double layer capacitor.

One embodiment of the present invention relates to a neural network and a system for estimating the state of charge of a power storage device using the neural network. One embodiment of the present invention relates to a vehicle using a neural network. One embodiment of the present invention relates to an electronic device using a neural network. One embodiment of the present invention is not limited to a vehicle, and can also be applied to a power storage device for storing electric power obtained from power generation facilities such as a solar power generation panel provided in a structure body or the like, and relates to a system for estimating the state of charge.

### BACKGROUND ART

As a method of estimating the remaining capacity of a secondary battery, a Coulomb counter method or an OCV (Open Circuit Voltage) method is used.

Conventional methods have a problem in that with repeated charge and discharge during a long-term operation, errors are accumulated to significantly decrease the estimation accuracy of a charge rate, i.e., SOC (State of Charge). In addition, when a battery remains unused, an initial SOC(0) changes due to self-discharge, which makes it difficult to increase the SOC estimation accuracy. The Coulomb counter method is disadvantageous in that, for example, an error of the initial SOC(0) cannot be corrected and errors of a current sensor are accumulated. Patent Document 1 discloses a technique for highly accurate estimation of the state of a secondary battery at a low temperature by a state estimation means based on data having a parameter associated with temperature.

### REFERENCE

### Patent Document

[Patent Document 1] Japanese Published Patent Application No. 2016-80693

### SUMMARY OF THE INVENTION

### Problems to be Solved by the Invention

Even through the manufacturing lot is the same, secondary batteries sometimes have slight individual differences caused by slight differences in, for example, the amount of an active material or the electrode size, at the time of assembling. A plurality of secondary batteries are used for vehicles, for example, and influences of individual differences bring degradation when a large number of batteries are combined, which makes a difference in capacity between the vehicles large in some cases. Even between the batteries in the same lot, the degree of degradation is different by the influence of the usage (environmental temperature, the frequency of charge and discharge, and the storage condition) or the like.

Furthermore, when degradation of a secondary battery progresses, the SOC estimation accuracy might significantly decrease. For example, with long-time use of an estimation method using current integration values, errors of current value detection are accumulated, so that the SOC estimation accuracy gradually decreases. Note that the SOC is defined as the proportion of remaining capacity to the maximum capacity of the secondary battery. When the maximum capacity of the secondary battery can be calculated from a time integral of current by discharging after full charging, full discharging might take a long time. Furthermore, the charging is needed again before the secondary battery is used.

A method of estimating the state of charge of a secondary battery that has high estimation accuracy even when degradation of the secondary battery progresses is provided. Furthermore, a capacity measurement system of a secondary battery that estimates an SOC with high estimation accuracy in a short time at low cost is provided.

When the capacity of a secondary battery can be estimated with high accuracy, an anomaly can also be detected in accordance with the value. Another object is to provide a novel method of detecting an anomaly of a secondary battery.

### Means for Solving the Problems

In the case where the state of charge of a secondary battery is estimated, a variety of parameter information of the secondary battery can be used. Examples of the parameter information of the secondary battery include internal resistance of the secondary battery, a current value, a voltage value, an ambient temperature, an internal temperature of the secondary battery, a capacity value in a full charge state, conditions of charging, and conditions of discharging. The use of a larger number of kinds of data does not necessarily achieve higher-accuracy estimation. In some cases, the use of many kinds of data brings the result containing much noise, which decreases the estimation accuracy. In addition, the use of many kinds of data requires many arithmetic processing, and sometimes, it takes time to output the solutions or the solution does not converge and the arithmetic processing does not terminate.

By a method of estimating the state of charge of a secondary battery disclosed in this specification, some parameters that directly or indirectly affect degradation of the secondary battery are found among many kinds of data, and a neural network learning device learns a smaller kinds of parameters as teacher data, so that the learning result of the neural network becomes the capacity of the secondary battery.

For the neural network learning device, an increase in the number of parameters and data does not necessarily increase the accuracy, and a large amount of data sometimes causes over-training, which decreases the estimation accuracy.

It is important that how a smaller number of learning parameters are selected and determined as teacher data among many parameters and learned by a neural network learning device so as to calculate the capacity of the secondary battery with high accuracy.

The present inventors performed charge and discharge cycles by the CCCV charging method and measured degradation of secondary batteries, and found that a period of time of CV charging (also referred to as CV time) becomes longer with degradation of a secondary battery. Lithium-ion secondary batteries are generally charged by the CCCV charging method. CCCV charging is a charging method in which CC charging is performed until the voltage reaches a predetermined voltage and then CV charging is performed until the amount of current flow becomes small, specifically, a termination current value. One charging period is separated to a CC charging period (also referred to as CC time) and a following CV charging period (CV time). In the CC charging period, a constant current flows through a secondary battery until a predetermined voltage is reached, and in the CV charging period, charging is performed with a constant voltage until a termination current value is reached.

In the CCCV charging method, the CC time and the CV time are used as learning parameters to construct a learning model. The construction of such a learning model indicates a learning stage (a learning phase).

As learning parameters used for the learning model, not only data of the CC time and the CV time, but also various data which can be actually obtained by the charge and discharge cycle tests of a reference secondary battery are used.

With this learning model, an estimated capacity value can be obtained with use of three of the CC time, the CV time, and a charge inception voltage value as the minimum input data. Obtaining the estimated capacity value from the learning results using the learning model means a determination stage (a determination phase). A driver can obtain an estimated capacity value in the case where the learning results are obtained in advance and at least the determination stage is mounted in a vehicle although both the learning stage and the determination stage may be mounted in the vehicle. In the case where data while the vehicle is moving is used as a learning parameter, both the learning stage and the determination stage are mounted in the vehicle, whereby the driver can obtain a more accurate estimated capacity value while the vehicle is moving.

In a method of estimating the capacity of a secondary battery disclosed in this specification, a charge inception voltage value of the secondary battery is measured, a first time (CC time) from when charging is started until when terminal voltage of the secondary battery reaches a reference voltage is measured, a second time (CV time) from when the terminal voltage reaches the reference voltage until when the charging is terminated is measured, and the capacity of the secondary battery is calculated by a neural network unit to which the charge inception voltage value, the first time, and the second time are input.

In the case where, fourth data, which is a voltage value after a third time until when a chemical reaction inside the secondary battery is stabilized after pause time after charge termination, is input in addition to the three values, the highest accuracy can be obtained though the number of input data is increased. Note that in the third time, a cycle test is performed on a reference secondary battery in advance, the pause is provided after charge termination, and time until when the chemical reaction inside the secondary battery is stabilized is measured.

In another method of estimating the capacity of a secondary battery disclosed in this specification, a charge inception voltage value of the secondary battery is measured, a first time (CC time) from when charging is started until when terminal voltage of the secondary battery reaches a reference voltage is measured, a second time (CV time) from when the terminal voltage reaches the reference voltage until when the charging is terminated is measured, a voltage value after a third time from when the charging is terminated until when a chemical reaction inside the secondary battery is stabilized is measured, and a charge state of the secondary battery, specifically, a capacity of the secondary battery is calculated by a neural network unit to which the charge inception voltage value, the first time (CC time), the second time (CV time), and the voltage value are input.

In the case of using a small number of data, the first time (CC time) from when charge of the secondary battery is started until when the terminal voltage of the secondary battery reaches a reference voltage is measured, the second time (CV time) from when the terminal voltage reaches the reference voltage until when the charging is terminated is measured, and a charge state of the secondary battery, specifically, a capacity of the secondary battery is calculated by a neural network unit to which two data of the first time and the second time are input. The capacity of the secondary battery can be calculated after the termination of the charge of the secondary battery or during discharge of the secondary battery (specifically, while a vehicle is moving) as appropriate.

CC charging and CV charging will be described below.

First, CC charging is described as one of the charging methods. CC charging is a charging method in which a constant current is made to flow to a secondary battery in the whole charging period and charging is stopped when the voltage reaches a predetermined voltage. The secondary battery is assumed to be an equivalent circuit with internal resistance R and secondary battery capacitance C as illustrated in FIG. 6A. In this case, a secondary battery voltage V_{B} is the sum of a voltage V_{R} applied to the internal resistance R and a voltage V_{C} applied to the secondary battery capacitance C.

While the CC charging is performed, a switch is on as illustrated in FIG. 6A, so that a constant current I flows to the secondary battery. During the period, the current I is constant; thus, in accordance with the Ohm's law (V_{R}=R×I), the voltage V_{R} applied to the internal resistance R is also constant. In contrast, the voltage V_{C} applied to the secondary battery capacitance C increases over time. Accordingly, the secondary battery voltage V_{B} increases over time.

When the secondary battery voltage V_{B} reaches a predetermined voltage, e.g., 4.3 V, the charging is stopped. When the CC charging is stopped, the switch is turned off as illustrated in FIG. 6B, and the current I becomes 0. Thus, the voltage V_{R} applied to the internal resistance R becomes 0 V. Consequently, the secondary battery voltage V_{B} decreases.

FIG. 6C shows an example of the secondary battery voltage V_{B} and charging current during a period in which the CC charging is performed and after the CC charging is stopped. The state is shown in which the secondary battery voltage V_{B}, which increases while the CC charging is performed, slightly decreases after the CC charging is stopped.

Next, CCCV charging, which is a charging method different from the above-described method, is described. CCCV charging is a charging method in which CC charging is performed until the voltage reaches a predetermined voltage and then CV charging is performed until the amount of current flow becomes small, specifically, a termination current value.

While the CC charging is performed, a switch of a constant current power source is on and a switch of a constant voltage power source is off as illustrated in FIG. 7A, so that the constant current I flows to the secondary battery. During the period, the current I is constant; thus, in accordance with the Ohm's law (V_{R}=R×I), the voltage V_{R} applied to the internal resistance R is also constant. In contrast, the voltage V_{C} applied to the secondary battery capacitance C increases over time. Accordingly, the secondary battery voltage V_{B} increases over time.

When the secondary battery voltage V_{B} reaches a predetermined voltage, e.g., 4.3 V, the CC charging is switched to the CV charging. While the CV charging is performed, the switch of the constant voltage power source is on and the switch of the constant current power source is off as illustrated in FIG. 7B; thus, the secondary battery voltage V_{B} is constant. In contrast, the voltage V_{C} applied to the secondary battery capacitance C increases over time. Since V_{B}=V_{R}+V_{C} is satisfied, the voltage V applied to the internal resistance R decreases over time. As the voltage V applied to the internal resistance R decreases, the current I flowing to the secondary battery also decreases in accordance with the Ohm's law (V_{R}=R×I).

When the current I flowing to the secondary battery becomes a predetermined current, e.g., a current corresponding to approximately 0.01 C, charging is stopped. When the CCCV charging is stopped, all the switches are turned off as illustrated in FIG. 7C, so that the current I becomes 0. Thus, the voltage V_{R} applied to the internal resistance R becomes 0 V. However, the voltage V_{R} applied to the internal resistance R becomes sufficiently small by the CV charging; thus, even when a voltage drop no longer occurs in the internal resistance R, the secondary battery voltage V_{B} hardly decreases.

FIG. 8A shows an example of the secondary battery voltage V_{B} and charging current while the CCCV charging is performed and after the CCCV charging is stopped. The state is shown in which the secondary battery voltage V_{B} hardly decreases even after the CCCV charging is stopped.

Next, CC discharging, which is one of discharging methods, is described. CC discharging is a discharging method in which a constant current is made to flow from the secondary battery in the whole discharging period, and discharging is stopped when the secondary battery voltage V_{B} reaches a predetermined voltage, e.g., 2.5 V.

FIG. 8B shows an example of the secondary battery voltage V_{B} and discharging current while the CC discharging is performed. The state is shown in which the secondary battery voltage V_{B} decreases as discharging proceeds.

Next, a discharging rate and a charging rate are described. The discharging rate refers to the relative ratio of discharging current to battery capacity and is expressed in a unit C. A current corresponding to 1 C in a battery with a rated capacity X(Ah) is X(A). The case where discharging is performed at a current of 2X(A) is rephrased as to perform discharging at 2 C, and the case where discharging is performed at a current of X/5 (A) is rephrased as to perform discharging at 0.2 C. The same applies to the charging rate; the case where charging is performed at a current of 2X(A) is rephrased as to perform charging at 2 C, and the case where charging is performed at a current of X/5 (A) is rephrased as to perform charging at 0.2 C.

The method of estimating the state of charge of a secondary battery disclosed in this specification is a method in which the degree of degradation of a secondary battery is basically estimated after charge termination not at the point of use. For example, the capacity of a secondary battery of an electric vehicle can be estimated with high accuracy when the charge is terminated. In this case, with a charge control device for charging the electric vehicle or a server capable of transmitting and receiving data with the charge control device, neural network processing is performed. In the case where the neural network processing is performed, hardware including memories adequate for accumulating learning data and capable of sufficient arithmetic processing is needed.

A program of the software executing an inference program for the neural network processing can be described in a variety of programing languages such as Python, Go, Perl, Ruby, Prolog, Visual Basic, C, C++, Swift, Java (registered trademark), and .NET. The application may be designed using a framework such as Chainer (it can be used with Python), Caffe (it can be used with Python and C++), and TensorFlow (it can be used with C, C++, and Python). For example, the algorithm of LSTM is programmed with Python, and a CPU (Central Processing Unit) or a GPU (Graphics Processing Unit) is used. A chip in which a CPU and a GPU are integrated is sometimes referred to as an APU (Accelerated Processing Unit), and this APU chip can also be used. An IC with an AI (system (also referred to as an inference chip) may be used. The IC with an AI system is sometimes referred to as a circuit performing neural network calculation (a microprocessor).

### Effect of the Invention

By the method of estimating the state of charge of a secondary battery disclosed in this specification, the capacity can be estimated with high accuracy with use of a small number of kinds of data. Accordingly, arithmetic processing can be simplified with use of a small amount of learning data.

The hardware capable of performing neural network processing can be reduced in size, and thus can be incorporated in a small charge control device. With use of a portable information terminal on which the hardware capable of performing neural network processing is mounted, the capacity of an electric vehicle can be estimated on the basis of charge information of the electric vehicle.

Furthermore, the small hardware can be mounted on an electric vehicle. When the small hardware is mounted on an electric vehicle, the capacity can be estimated with high accuracy after charge on a charge spot at a destination.

### BRIEF DESCRIPTION OF THE DRAWINGS

FIG. 1A is a graph showing the estimation accuracy by a method of one embodiment of the present invention, FIG. 1B is a table showing kinds of input data, and FIG. 1C is a table corresponding to FIG. 1A.

FIG. 2A is a graph showing the estimation accuracy by a method of one embodiment of the present invention, and FIG. 2B and FIG. 2C are tables showing kinds of input data.

FIG. 3 is a flowchart showing one embodiment of the present invention.

FIG. 4 is data showing pause time and a change in voltage after charge of a secondary battery.

FIG. 5A and FIG. 5B are diagrams showing an example of arithmetic operation in the neural network processing.

FIG. 6A, FIG. 6B, and FIG. 6C are diagrams showing a method of charging a secondary battery.

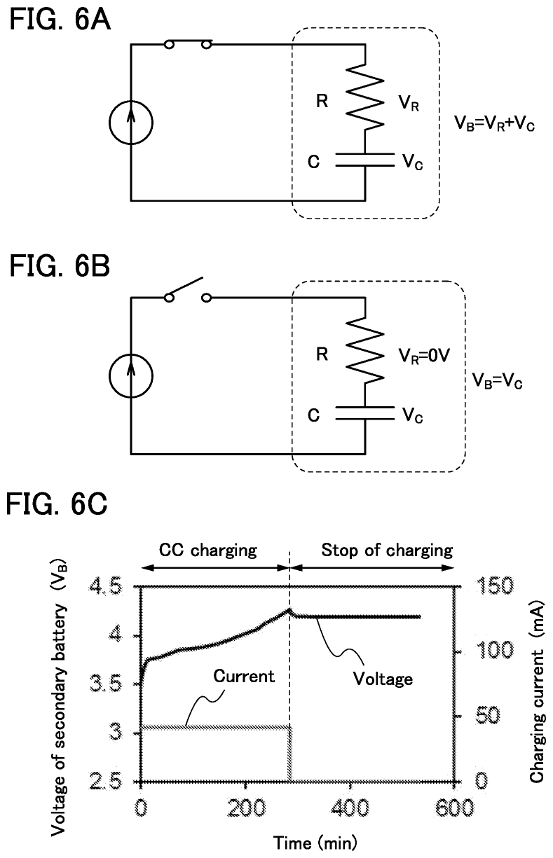

FIG. 7A, FIG. 7B, and FIG. 7C are diagrams showing a method of charging a secondary battery.

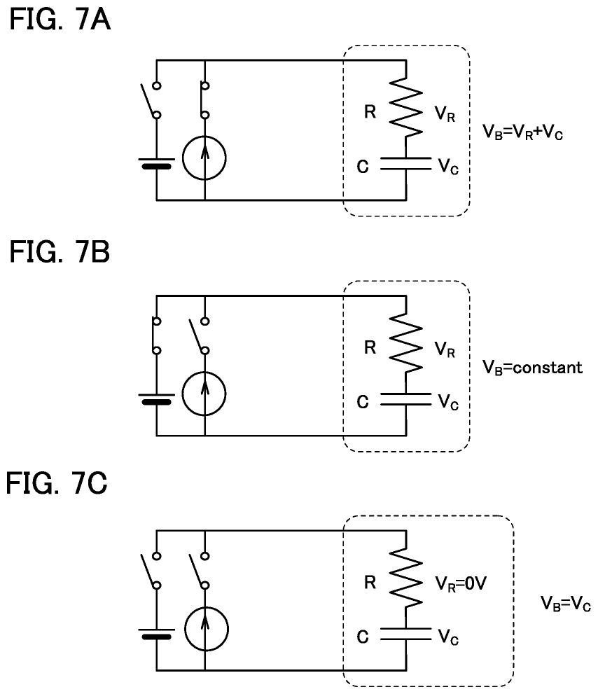

FIG. 8A and FIG. 8B show a charge curve of a secondary battery and a discharge curve of the secondary battery, respectively.

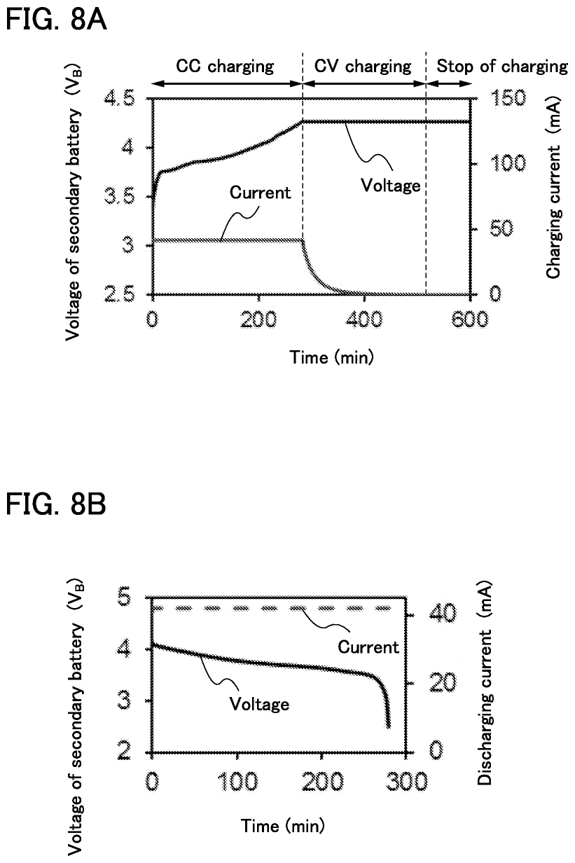

FIG. 9A and FIG. 9B are diagrams illustrating a coin-type secondary battery.

FIG. 10A is a perspective view, FIG. 10B is a cross-sectional perspective view, FIG. 10C is a perspective view, and FIG. 10D is a top view, which illustrate a cylindrical secondary battery.

FIG. 11A, FIG. 11B, and FIG. 11C are perspective views illustrating examples of secondary batteries.

FIG. 12A, FIG. 12B, FIG. 12C, FIG. 12D, and FIG. 12E are diagrams illustrating examples of small electronic devices and vehicles each including a secondary battery module of one embodiment of the present invention.

FIG. 13A, FIG. 13B, and FIG. 13C are diagrams illustrating examples of a vehicle and a house each including a secondary battery module of one embodiment of the present invention.

FIG. 14 shows the program of one embodiment of the present invention and an information processing method.

FIG. 15 shows the program of one embodiment of the present invention and an information processing method.

FIG. 16 shows the program of one embodiment of the present invention and an information processing method.

FIG. 17 shows the program of one embodiment of the present invention and an information processing method.

FIG. 18 shows the program of one embodiment of the present invention and an information processing method.

### MODE FOR CARRYING OUT THE INVENTION

Embodiments of the present invention are described in detail below with reference to the drawings. Note that the present invention is not limited to the following description, and it is readily understood by those skilled in the art that modes and details of the present invention can be modified in various ways. In addition, the present invention should not be construed as being limited to the description of the embodiments below.

### Embodiment 1

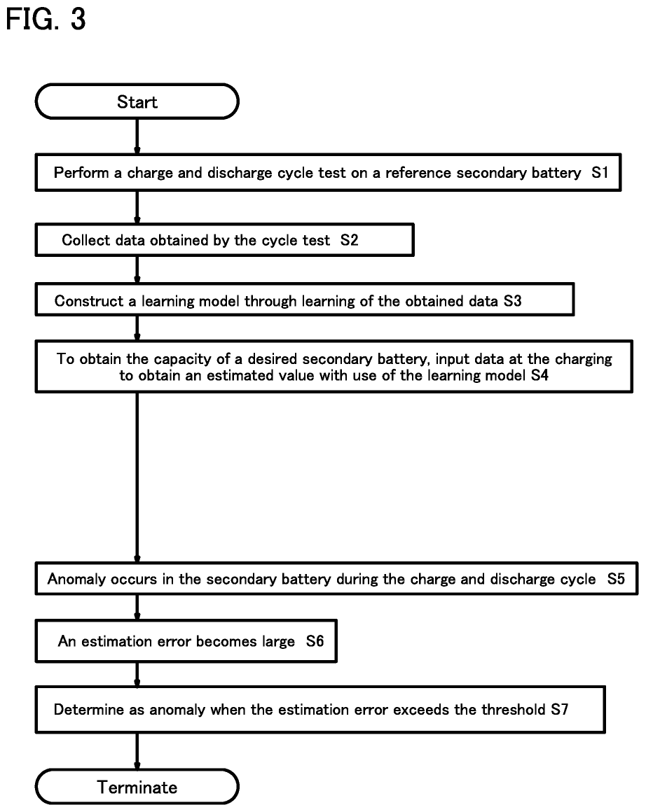

In this embodiment, a procedure in which a cycle test is performed on a reference secondary battery, a learning model based on the data is constructed, and the capacity is estimated and a procedure in which anomaly detection is performed with the model are shown in FIG. 3.

First, a charge and discharge cycle test is performed on the reference secondary battery.

### (S1)

Data obtained by the charge and discharge cycle test is collected. (S2) In this data collection, a variety of data is collected. For example, the CC time, the CV time, temperature, discharge voltage, initial FCC (mAh), the number of cycles, the charge inception voltage, voltage one second after the charge inception, voltage two seconds after the charge inception, voltage 60 seconds after the charge inception, voltage 120 seconds after the charge inception, voltage immediately after the charge termination, voltage after a pause of one second after the charge termination, voltage after a pause of two seconds after the charge termination, voltage after a pause of ten seconds after the charge termination, voltage after a pause of 120 seconds after the charge termination, voltage after a pause of 600 seconds after the charge termination, and the like are actually measured. These data (excepting the number of cycles) can be obtained by one cycle of charge and discharge. Furthermore, the data can be obtained at and after the second cycle of charge and discharge. A plurality of secondary batteries can be used as the reference secondary batteries as long as they have substantially the same characteristics.

At least three data, which are the CC time, the CV time, and the charge inception voltage, are collected. In this embodiment, a plurality of commercially available lithium-ion secondary batteries (NCR18650B) are used for the cycle test to obtain data. The nominal capacity of the lithium-ion secondary battery is 3350 mAh, and the average voltage is 3.6 V. As the cycle test, an operation in which charging with 4.2 V and 0.5 C (CV cut-off 0.02 C) is performed, a 10-minute pause is provided, discharge is performed until the voltage becomes a predetermined voltage, and a 10-minute pause is provided is repeated.

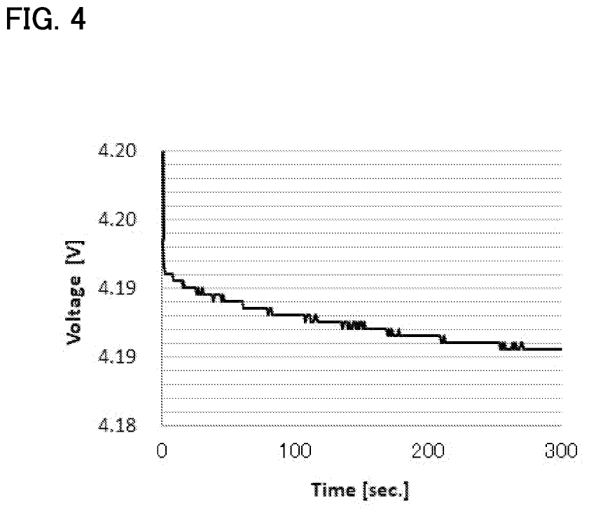

Data at the time of the pause after the charge termination is also collected in advance. As for this data, after the lithium-ion secondary battery is fully charged, data is collected in such a manner that a pause (being left uncontrolled) time is represented by the horizontal axis and voltage is represented by the vertical axis, and a time when a change in voltage is small is selected. FIG. 4 shows actually measured values of a graph showing a change in voltage with time from the pause after the full charge termination. In FIG. 4, the change in voltage is small in a range from approximately 110 seconds to approximately 130 seconds after the beginning of the pause. This point in time when the change is small corresponds to the point in time until when the chemical reaction inside the secondary battery is stabilized. Note that in the secondary battery that is actually subjected to 1000 times of cycle tests, internal resistance increases due to degradation and a voltage drop becomes large, and substantially the same tendency is observed as for a time passage of voltage after the full charge termination. In this embodiment, the value of voltage 120 seconds (two minutes) after the beginning of the pause is used as an important parameter. Note that the time until when the chemical reaction inside the secondary battery is stabilized differs depending on the type of the secondary battery, and may be determined from data obtained by cycle tests using a secondary battery on which capacity estimation is desired to be performed.

Next, a learning model is constructed through learning of the obtained data. (S3)

In this embodiment, the learning is performed in such a manner that optimum weight and bias are set for each node at which neurons are connected to create a learning model. Chainer is used as a framework, and full-connected neural network processing is performed on the basis of the MNIST official source. The number of intermediate layers is three and the number of hidden layers is 200. Note that Adam is used as an optimizer that performs optimization. As the learning data, at least three data, which are the CC time, the CV time, and the charge inception voltage, are used and capacity available for discharging is learned as a correct label. For the learning, data subjected to linear interpolation and normalization is used.

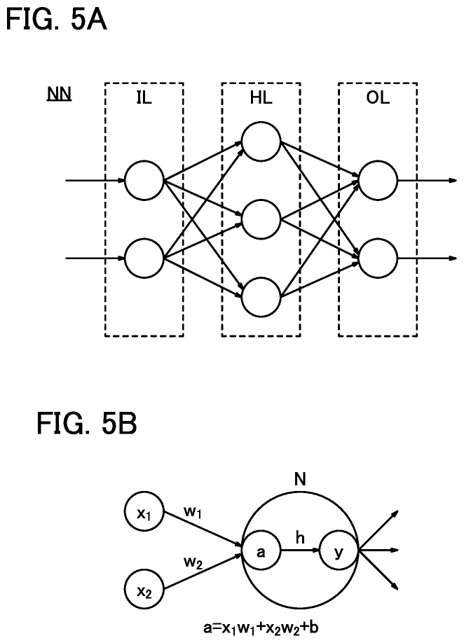

FIG. 5A and FIG. 5B show an example of arithmetic operation in the neural network processing.

As illustrated in FIG. 5A, neural network processing NN can be composed of an input layer IL, an output layer OL, and a middle layer (hidden layer) HL. The input layer IL, the output layer OL, and the middle layer HL each include one or more neurons (units). Note that the middle layer HL may be composed of one layer or two or more layers. Neural network processing including two or more middle layers HL can also be referred to as DNN (deep neural network), and learning using deep neural network processing can also be referred to as deep learning.

Input data is input to each neuron of the input layer IL, output signals of neurons in the previous layer or the subsequent layer are input to each neuron of the middle layer HL, and output signals of neurons in the previous layer are input to each neuron of the output layer OL. Note that each neuron may be connected to all the neurons in the previous and subsequent layers (full connection), or may be connected to some of the neurons.

FIG. 5B shows an example of an operation with the neurons. Here, a neuron N and two neurons in the previous layer which output signals to the neuron N are shown. An output x₁ of the neuron in the previous layer and an output x₂ of the neuron in the previous layer are input to the neuron N. Then, in the neuron N, a total sum x₁w₁+x₂w₂ of the product of the output x₁ and a weight w₁ (x₁w₁) and the product of the output x₂ and a weight w₂ (x₂w₂) is calculated, and then a bias b is added as necessary, so that a value α=x₁w₁+x₂w₂+b is obtained. Then, the value α is converted with an activation function h, and an output signal y=h(α) is output from the neuron N.

In this manner, the operation with the neurons includes the operation that sums the products of the input data and the weights, that is, a product-sum operation. This product-sum operation can be performed by a product-sum operation circuit including a current supply circuit, an offset absorption circuit, and a cell array. In addition, signal conversion with the activation function h can be performed by a hierarchical output circuit. In other words, the operation of the middle layer or the output layer can be performed by an operation circuit.

The cell array included in the product-sum operation circuit is composed of a plurality of memory cells arranged in a matrix.

The memory cells each have a function of storing first data. The first data is data corresponding to the weight between the neurons of the neural network processing. In addition, the memory cells each have a function of multiplying the first data by second data that is input from the outside of the cell array. That is, the memory cells have a function of a memory circuit and a function of a multiplier circuit.

Note that in the case where the first data is analog data, the memory cells have a function of an analog memory. Alternatively, in the case where the first data is multilevel data, the memory cells have a function of a multilevel memory.

The multiplication results in the memory cells in the same column are summed up. Thus, the product-sum operation of the first data and the second data is performed. Then, the results of the operation in the cell array are output to the hierarchical output circuit as third data.

The hierarchical output circuit has a function of converting the third data output from the cell array in accordance with a predetermined activation function. An analog signal or a multilevel digital signal output from the hierarchical output circuit corresponds to the output data of the middle layer or the output layer in the neural network processing.

As the activation function, a sigmoid function, a tan h function, a softmax function, a ReLU function, a threshold function, or the like can be used, for example. The signal converted by the hierarchical output circuit is output as analog data or multilevel digital data (data D_{analog}).

In this manner, one of the operations of the middle layer and the output layer in the neural network processing can be performed by one operation circuit.

Analog data or multilevel digital data output from a first operation circuit is supplied to a second operation circuit as the second data. Then, the second operation circuit performs an operation using the first data stored in the memory cells and the second data input from the first operation circuit. Thus, operation of neural network processing composed of a plurality of layers can be performed.

To obtain the capacity of a desired secondary battery, an estimated value is obtained by inputting data at the charging with use of the learning model. (S4)

With use of the learning model using three data, which are the CC time, the CV time, and the charge inception voltage, as learning data, these data are input as Input 1, whereby the mean error can be 6.088 mAh.

With use of the learning model using five data, which are the CC time, the CV time, the charge inception voltage, voltage one second after the charge termination, and voltage two seconds after the charge termination, as learning data, these data are input as Input 2, whereby the mean error can be 6.382 mAh.

With use of the learning model using four data, which are the CC time, the CV time, the charge inception voltage, and voltage 120 seconds after the charge termination, as learning data, these data are input as Input 3, whereby the mean error can be 5.844 mAh.

With use of the learning model using six data, which are the CC time, the CV time, the charge inception voltage, voltage one second after the charge termination, voltage two seconds after the charge termination, and a ratio of the CC time to the CV time (CCCV time ratio), as learning data, these data are input as Input 4, whereby the mean error can be 6.66 mAh.

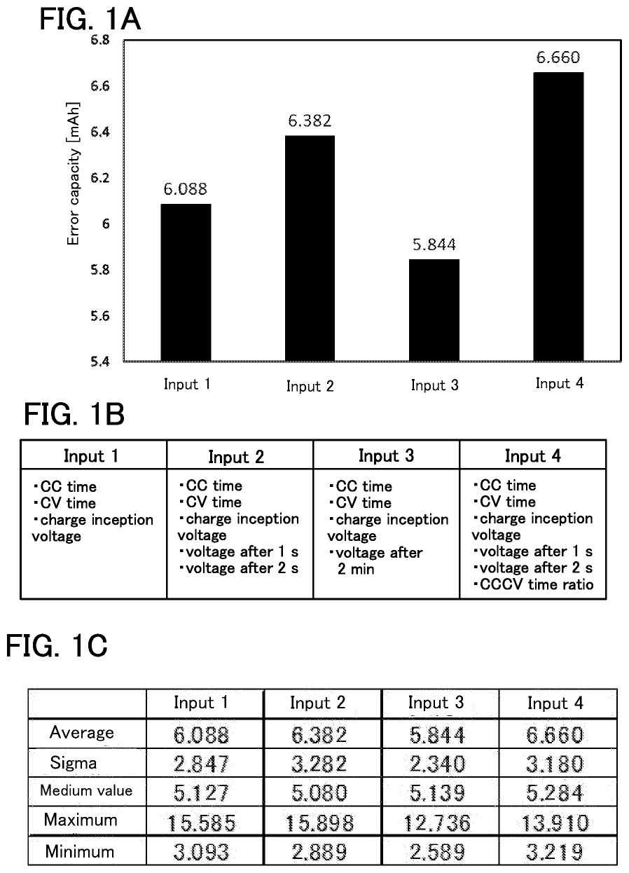

FIG. 1A shows a bar graph comparing these results, FIG. 1B shows an input table, and FIG. 1C shows a mean error list.

According to these results, with use of at least three data, which are the CC time, the CV time, and the charge inception voltage, an error of the estimated capacity value can be suppressed as small as approximately 7 mAh; in particular, with use of the learning model using four data, which are the CC time, the CV time, the charge inception voltage, and voltage 120 seconds after the charge termination, as learning data, the capacity can be estimated with the highest accuracy.

Step S1 to Step S4 can be referred to as a procedure in which a learning model is constructed and the capacity is estimated.

Only normal data is learned as the learning data. Accordingly, if anomaly occurs in a secondary battery, the estimated value is changed and an estimation error becomes large. This can be utilized for anomaly detection.

The secondary battery is subsequently used and charged, that is, a charge and discharge cycle is performed, and after the charge termination, the capacity is estimated using the learning model.

Step 5 (S5) in which anomaly occurs in a secondary battery during a charge cycle is assumed.

An estimation error after the occurrence of anomaly is calculated, and a large estimation error is output. (S6)

When the estimation error at S6 exceeds the threshold of the estimation error that can be regarded as the occurrence of anomaly, it is determined as anomaly. (S7)

Note that in order to distinguish noise occurrence and anomaly occurrence, the threshold of the estimation error is determined in advance.

If anomaly occurs, the anomaly can be detected through Steps S5, S6, and S7.

The procedure of capacity estimation is shown using the flowchart in FIG. 3 as described above, and the results in FIG. 1 show that high-accuracy capacity estimation can be performed. In addition, the procedure of anomaly detection is shown using the flowchart in FIG. 3, and the anomaly detection is performed on the basis of the high-accuracy capacity estimation.

Note that the estimation error refers to a difference between a value estimated using the learning model and the capacity available for discharging, and the mean error refers to an average of the estimation error in each of battery cells used. Since ten battery cells are used in this embodiment, a total of estimation errors of the ten battery cells is divided by ten, whereby the mean error is obtained.

### Embodiment 2

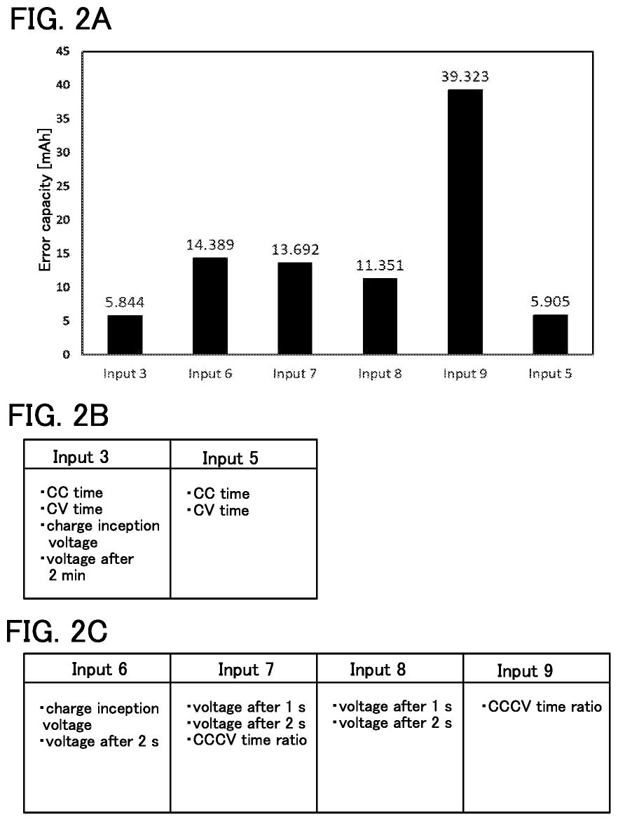

In this embodiment, a comparison with a comparative example, which is different from that in Embodiment 1, will be described below with reference to FIG. 2.

FIG. 2A shows the results of estimation errors obtained by using the same learning model as that in Embodiment 1 and changing input data variously.

Note that Input 3 shown in FIG. 2A and FIG. 2B is the same as Input 3 shown in FIG. 1A, and results under the same conditions are shown.

Input 5 shown in FIG. 2A and FIG. 2B is the results obtained by using the CC time and the CV time, and is one embodiment of the present invention. In Input 5, the average value is 5.9 and the minimum value is 3.2 as compared with Input 3; accordingly, the estimation accuracy is lower than that of Input 3.

Input 6, Input 7, Input 8, and Input 9 shown in FIG. 2C are comparative examples, and the estimation error of each of the comparative examples is greater than or equal to 10 (mAh). As data for Input 6, the charge inception voltage and voltage after a pause of 120 seconds after the charge termination are used. As data for Input 7, voltage one second after the charge termination, voltage two seconds after the charge termination, and the CCCV time ratio are used. As data for Input 8, voltage one second after the charge termination and voltage two seconds after the charge termination are used. As data for Input 9, the CCCV time ratio is used.

For each Input, estimated capacities of ten battery cells are calculated and the average thereof is shown as an error capacity (mAh).

According to the results of FIG. 2A, at least the CC time and the CV time, and furthermore the charge inception voltage and voltage after a pause of 120 seconds after the charge termination are used for the learning model, whereby the estimated capacity with the highest accuracy can be output as compared with the learning models using other conditions. In the case where the number of data is desired to be small, a learning model using two data, which are the CC time and the CV time, is preferably employed.

### Embodiment 3

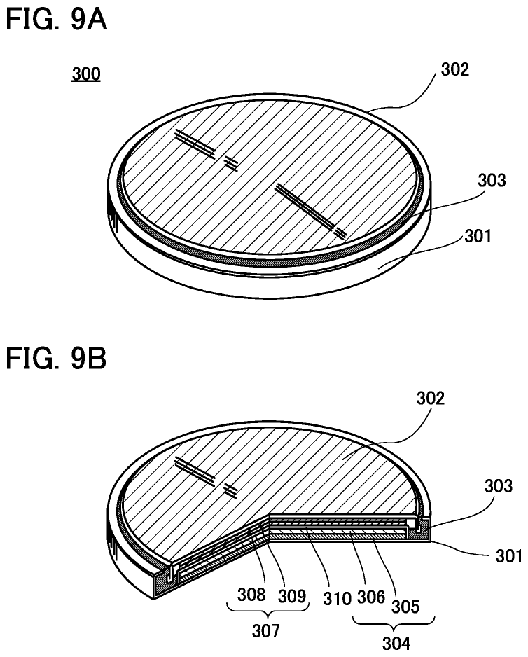

An example of a coin-type secondary battery is described. FIG. 9A is an external view of a coin-type (single-layer flat type) secondary battery, and FIG. 9B is a cross-sectional view thereof.

In a coin-type secondary battery 300, a positive electrode can 301 doubling as a positive electrode terminal and a negative electrode can 302 doubling as a negative electrode terminal are insulated from each other and sealed by a gasket 303 made of polypropylene or the like. A positive electrode 304 includes a positive electrode current collector 305 and a positive electrode active material layer 306 provided in contact with the positive electrode current collector 305. A negative electrode 307 includes a negative electrode current collector 308 and a negative electrode active material layer 309 provided in contact with the negative electrode current collector 308.

Note that an active material layer may be formed over only one surface of each of the positive electrode 304 and the negative electrode 307 used for the coin-type secondary battery 300.

For the positive electrode can 301 and the negative electrode can 302, a metal having corrosion resistance to an electrolyte solution, such as nickel, aluminum, or titanium, an alloy of such a metal, or an alloy of such a metal and another metal (e.g., stainless steel) can be used. The positive electrode can 301 and the negative electrode can 302 are preferably covered with nickel, aluminum, or the like in order to prevent corrosion due to the electrolyte solution. The positive electrode can 301 and the negative electrode can 302 are electrically connected to the positive electrode 304 and the negative electrode 307, respectively.

The coin-type secondary battery 300 is manufactured in the following manner: the negative electrode 307, the positive electrode 304, and a separator 310 are immersed in the electrolyte solution; as illustrated in FIG. 9B, the positive electrode 304, the separator 310, the negative electrode 307, and the negative electrode can 302 are stacked in this order with the positive electrode can 301 positioned at the bottom; and then the positive electrode can 301 and the negative electrode can 302 are subjected to pressure bonding with the gasket 303 therebetween.

### [Cylindrical Secondary Battery]

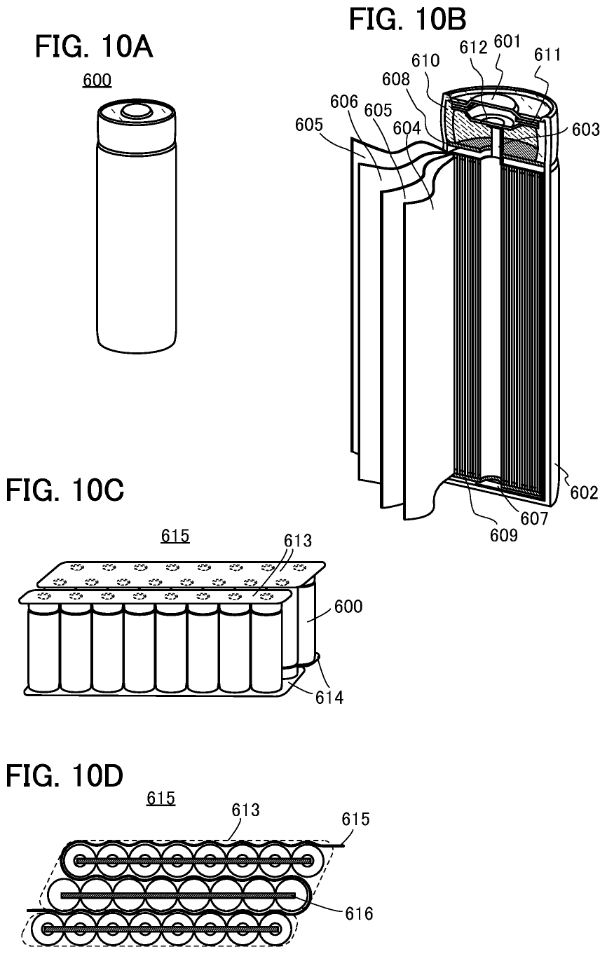

Next, an example of a cylindrical secondary battery is described with reference to FIG. 10A to FIG. 10D. A cylindrical secondary battery 600 includes, as illustrated in FIG. 10A, a positive electrode cap (battery lid) 601 on the top surface and a battery can (outer can) 602 on the side and bottom surfaces. The positive electrode cap and the battery can (outer can) 602 are insulated from each other by a gasket (insulating packing) 610.

FIG. 10B is a diagram schematically illustrating a cross-section of the cylindrical secondary battery. Inside the battery can 602 having a hollow cylindrical shape, a battery element in which a belt-like positive electrode 604 and a belt-like negative electrode 606 are wound with a separator 605 therebetween is provided. Although not illustrates, the battery element is wound centering around a center pin. One end of the battery can 602 is closed and the other end thereof is open. For the battery can 602, a metal having a corrosion-resistant property to an electrolyte solution, such as nickel, aluminum, or titanium, an alloy of such a metal, or an alloy of such a metal and another metal (e.g., stainless steel) can be used. The battery can 602 is preferably covered with nickel, aluminum, or the like in order to prevent corrosion due to the electrolyte solution. Inside the battery can 602, the battery element in which the positive electrode, the negative electrode, and the separator are wound is sandwiched between a pair of insulating plates 608 and 609 that face each other. Furthermore, a nonaqueous electrolyte (not illustrated) is injected inside the battery can 602 provided with the battery element. As the nonaqueous electrolyte, a nonaqueous electrolyte similar to that for a coin-type secondary battery can be used.

Since a positive electrode and a negative electrode that are used for a cylindrical storage battery are wound, active materials are preferably formed on both surfaces of a current collector. A positive electrode terminal (positive electrode current collector lead) 603 is connected to the positive electrode 604, and a negative electrode terminal (negative electrode current collector lead) 607 is connected to the negative electrode 606. For both the positive electrode terminal 603 and the negative electrode terminal 607, a metal material such as aluminum can be used. The positive electrode terminal 603 and the negative electrode terminal 607 are resistance-welded to a safety valve mechanism 612 and the bottom of the battery can 602, respectively. The safety valve mechanism 612 is electrically connected to the positive electrode cap 601 through a PTC (Positive Temperature Coefficient) element 611. The safety valve mechanism 612 cuts off electrical connection between the positive electrode cap 601 and the positive electrode 604 when the internal pressure of the battery increases exceeding a predetermined threshold value. In addition, the PTC element 611 is a thermally sensitive resistor whose resistance increases as temperature rises, and limits the amount of current by increasing the resistance to prevent abnormal heat generation. Barium titanate (BaTiO₃)-based semiconductor ceramics or the like can be used for the PTC element.

As illustrated in FIG. 10C, a plurality of secondary batteries 600 may be provided between a conductive plate 613 and a conductive plate 614 to form a module 615. The plurality of secondary batteries 600 may be connected in parallel, connected in series, or connected in series after being connected in parallel. With the module 615 including the plurality of secondary batteries 600, large electric power can be extracted.

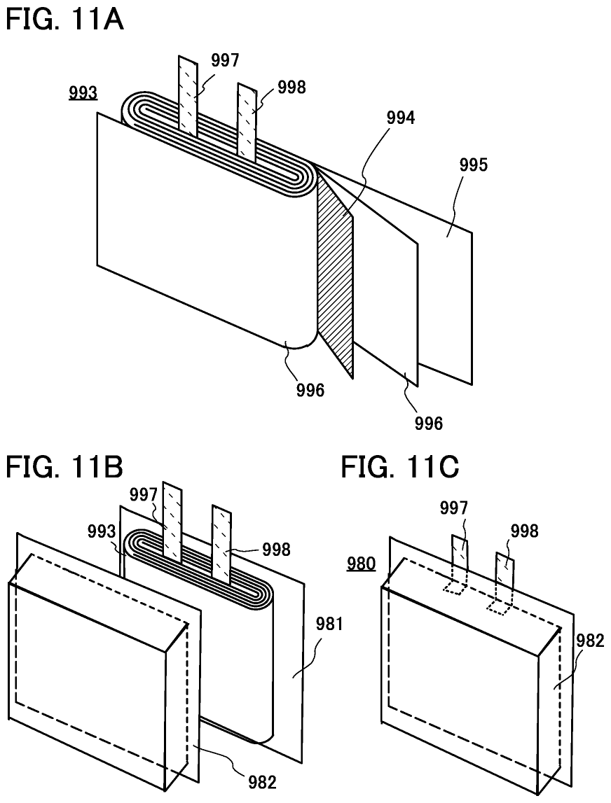

FIG. 10D is a top view of the module 615. The conductive plate 613 is shown by a dotted line for clarity of the drawing. As illustrated in FIG. 10D, the module 615 may include a conductive wire 616 electrically connecting the plurality of secondary batteries 600 with each other. It is possible to provide the conductive plate over the conductive wire 616 to overlap with each other. In addition, a temperature control device may be provided between the plurality of secondary batteries 600. The secondary batteries 600 can be cooled with the temperature control device when overheated, whereas the secondary batteries 600 can be heated with the temperature control device when cooled too much. Thus, the performance of the module 615 is less likely to be influenced by the outside temperature. A heating medium included in the temperature control device preferably has an insulating property and incombustibility.

[Structure Example of Secondary Battery]A laminated secondary battery 980 is described with reference to FIG. 11A, FIG. 11B, and FIG. 11C. The laminated secondary battery 980 includes a wound body 993 illustrated in FIG. 11A. The wound body 993 includes a negative electrode 994, a positive electrode 995, and separators 996. The wound body 993 is obtained by winding a sheet of a stack in which the negative electrode 994 and the positive electrode 995 overlap each other with the separator 996 sandwiched therebetween.

As illustrated in FIG. 11B, the wound body 993 is packed in a space formed by bonding a film 981 and a film 982 having a depressed portion that serve as exterior bodies by thermocompression bonding or the like, whereby the secondary battery 980 illustrated in FIG. 11C can be formed. The wound body 993 includes a lead electrode 997 and a lead electrode 998, and is immersed in an electrolyte solution inside a space surrounded by the film 981 and the film 982 having a depressed portion.

For the film 981 and the film 982 having a depressed portion, a metal material such as aluminum or a resin material can be used, for example. With the use of a resin material for the film 981 and the film 982 having a depressed portion, the film 981 and the film 982 having a depressed portion can be changed in their forms when external force is applied; thus, a flexible storage battery can be formed.

Although FIG. 11B and FIG. 11C illustrate an example of using two films for sealing, a space may be formed by bending one film and the wound body 993 may be packed in the space.

There is no particular limitation on the kinds of the secondary batteries in FIG. 9A to FIG. 11C described in this embodiment.

In the case where an electronic device or a vehicle is manufactured with use of any one of the secondary batteries in FIG. 9A to FIG. 11C, time until when a chemical reaction inside the secondary battery is stabilized may be measured in advance and a system that performs capacity estimation or anomaly detection in accordance with the flowchart in FIG. 3 may be constructed. This embodiment can be freely combined with Embodiment 1 or Embodiment 2.

In order to mount the learning model described in Embodiment 1, hardware such as GPU may be mounted on an electronic device or a vehicle. By the mounting, a system that estimates the capacity of the secondary battery with high accuracy can be prepared. After the charge of the secondary battery, a system that performs two-way communication with a server capable of neural network processing using the learning model may be constructed.

### Embodiment 4

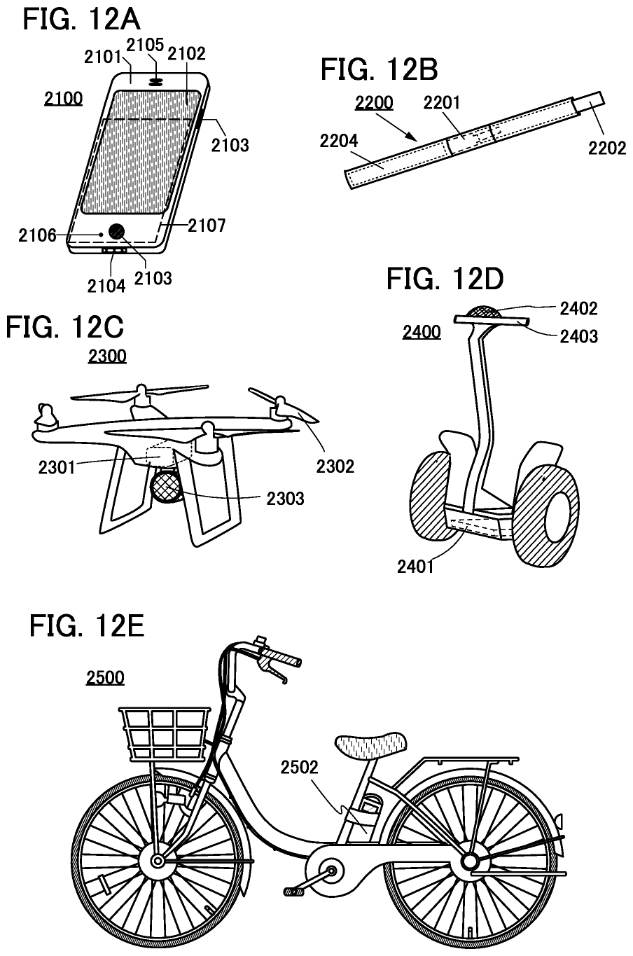

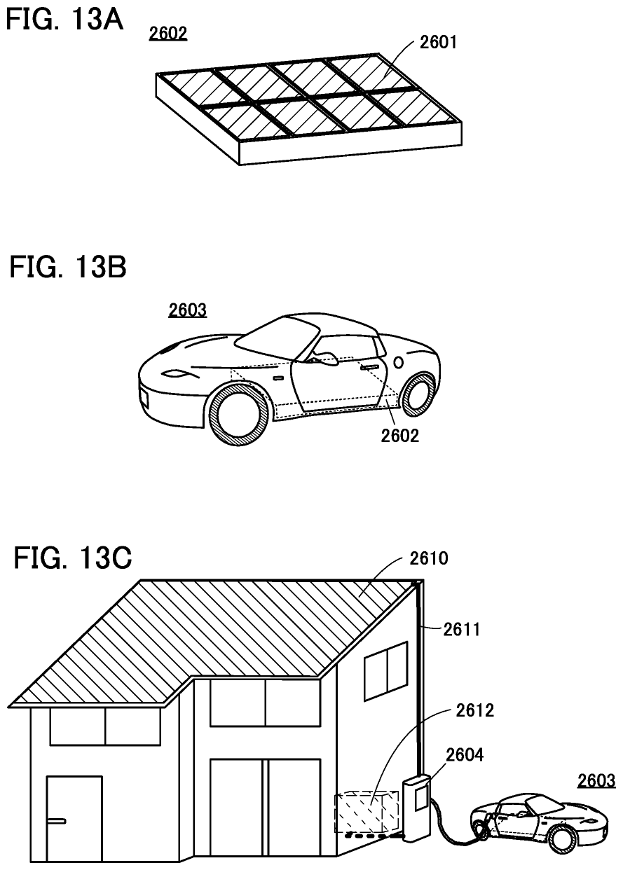

In this embodiment, an example of constructing a system that performs the capacity estimation of a secondary battery with high accuracy, which is described in the above embodiment, on a secondary battery in an electronic device will be described with reference to FIG. 12A to FIG. 12E and FIG. 13A to FIG. 13C. Note that the secondary battery module includes at least a secondary battery and a protection circuit.

First, examples of small electronic devices each including a secondary battery module will be described with reference to FIG. 12A to FIG. 12C.

FIG. 12A illustrates an example of a mobile phone. A mobile phone 2100 includes a housing 2101 in which a display portion 2102 is incorporated, an operation button 2103, an external connection port 2104, a speaker 2105, a microphone 2106, and the like. Note that the mobile phone 2100 includes a secondary battery module 2107.

The mobile phone 2100 is capable of executing a variety of applications such as mobile phone calls, e-mailing, viewing and editing texts, music reproduction, Internet communication, and computer games.

With the operation button 2103, a variety of functions such as time setting, power on/off operation, wireless communication on/off operation, execution and cancellation of a silent mode, and execution and cancellation of a power saving mode can be performed. For example, the functions of the operation button 2103 can also be set freely by an operating system incorporated in the mobile phone 2100.

In addition, the mobile phone 2100 can execute near field communication conformable to a communication standard. For example, mutual communication with a headset capable of wireless communication enables hands-free calling.

Moreover, the mobile phone 2100 includes the external connection port 2104, and data can be directly transmitted to and received from another information terminal via a connector. In addition, charging can be performed via the external connection port 2104. Note that the charging operation may be performed by wireless power feeding without using the external connection port 2104.

The mobile phone 2100 preferably includes a sensor. As the sensor, for example, a human body sensor such as a fingerprint sensor, a pulse sensor, or a temperature sensor, a touch sensor, a pressure sensitive sensor, an acceleration sensor, or the like is preferably mounted.

The mobile phone 2100 can estimate the capacity with high accuracy using a learning model constructed in a charger or a server capable of performing two-way communication with the charger after the mobile phone 2100 is charged with the charger. Furthermore, anomaly detection can also be performed with use of the estimated capacity.

FIG. 12B is a perspective view of a device called a cigarette smoking device (electronic cigarette). In FIG. 12B, an electronic cigarette 2200 includes a heating element 2201 and a secondary battery module 2204 that supplies electric power to the heating element 2201. A stick 2202 is inserted into this, and the stick 2202 is heated by the heating element 2201. To increase safety, a protection circuit for preventing overcharge and overdischarge of the secondary battery module 2204 may be electrically connected to the secondary battery module 2204. The secondary battery module 2204 illustrated in FIG. 12B includes an external terminal for connection to a charger. The secondary battery module 2204 is a tip portion when the electronic cigarette 2200 is held; thus, it is desirable that the secondary battery module 2204 have a short total length and be lightweight. Since the secondary battery module of one embodiment of the present invention has a high level of safety, the small and lightweight electronic cigarette 2200 that can be used safely for a long time over a long period can be provided.

The secondary battery module 2204 can estimate the capacity with high accuracy using a learning model constructed in a charger or a server capable of performing two-way communication with the charger after the secondary battery module 2204 is charged with the charger. Furthermore, anomaly detection can also be performed with use of the estimated capacity.

When the anomaly detection is performed after the charge using the learning model, the safety of the secondary battery module can be increased, whereby the small and light-weight electronic cigarette 2200 which can be used safely for a long time in a long period can be provided.

FIG. 12C illustrates an unmanned aircraft 2300 including a plurality of rotors 2302. The unmanned aircraft 2300 includes a secondary battery module 2301, a camera 2303, and an antenna (not illustrated). The unmanned aircraft 2300 can be remotely controlled through the antenna. The secondary battery module of one embodiment of the present invention has a high level of safety, and thus can be used safely for a long time over a long period and is suitable as the secondary battery module incorporated in the unmanned aircraft 2300.

The secondary battery module 2301 can estimate the capacity with high accuracy using a learning model constructed in a charger or a server capable of performing two-way communication with the charger after the secondary battery module 2301 is charged with the charger. Furthermore, anomaly detection can also be performed with use of the estimated capacity.

When the anomaly detection is performed after the charge using the learning model, the safety of the secondary battery module can be increased, whereby the secondary battery module can be used safely for a long time in a long period and is suitable as a secondary battery module mounted on the unmanned aircraft 2300.

Next, an example of mounting the capacity estimation system or the anomaly detection system of a secondary battery, each of which is one embodiment of the present invention, on a vehicle is described with reference to FIG. 12D, FIG. 12E, and FIG. 13A to FIG. 13C.

FIG. 12D illustrates an electric two-wheeled vehicle 2400 using a secondary battery module. The electric two-wheeled vehicle 2400 includes a secondary battery module 2401, a display portion 2402, and a handle 2403. The secondary battery module 2401 can supply electricity to a motor serving as a power source. The display portion 2402 can display the remaining battery level of the secondary battery module 2401, the velocity and horizontal state of the electric two-wheeled vehicle 2400, and the like.

FIG. 12E is an example of an electric bicycle using a secondary battery module. An electric bicycle 2500 includes a battery pack 2502. The battery pack 2502 includes a secondary battery module.

The battery pack 2502 can supply electricity to a motor that assists a rider. Furthermore, the battery pack 2502 can be taken off from the electric bicycle 2500 and carried. The battery pack 2502 and the electric bicycle 2500 may each include a display portion for displaying the remaining battery level and the like.

The battery pack 2502 can estimate the capacity with high accuracy using a learning model constructed in a charger or a server capable of performing two-way communication with the charger after the battery pack 2502 is charged with the charger. Furthermore, anomaly detection can also be performed with use of the estimated capacity.

When the anomaly detection is performed after the charge using the learning model, the safety of the battery pack 2502 can be increased, and thus the battery pack 2502 can be used safely for a long time in a long period and is suitable as an anomaly detection system mounted on the electric bicycle 2500.

Furthermore, as illustrated in FIG. 13A, a secondary battery module 2602 including a plurality of secondary batteries 2601 may be mounted on a hybrid electric vehicle (HEV), an electric vehicle (EV), a plug-in hybrid electric vehicle (PHEV), or another electronic device.

FIG. 13B illustrates an example of a vehicle including the secondary battery module 2602. A vehicle 2603 is an electric vehicle that runs using an electric motor as a power source. Alternatively, the vehicle 2603 is a hybrid electric vehicle that can run using a power source appropriately selected from an electric motor and an engine. The vehicle 2603 using the electric motor includes a plurality of ECUs (Electronic Control Units) and performs engine control by the ECUs. The ECU includes a microcomputer. The ECU is connected to a CAN (Controller Area Network) provided in the electric vehicle. The CAN is a type of a serial communication standard used as an in-vehicle LAN. The use of one embodiment of the present invention can achieve a vehicle with a high level of safety and a high mileage.

For the ECU, a CPU or a GPU is used. A chip in which a CPU and a GPU are integrated is sometimes called an APU (Accelerated Processing Unit), and this APU chip can also be used. An IC with an AI (system (also referred to as an inference chip) may be used. The secondary battery module 2602 can estimate the capacity with high accuracy using a learning model constructed in a charger, ECU, or a server capable of performing two-way communication with the charger after the secondary battery module 2602 is charged with the charger. Furthermore, anomaly detection can also be performed with use of the estimated capacity.

When the anomaly detection is performed after the charge using the learning model, the safety of the secondary battery module can be increased, and thus the secondary battery module can be used safely for a long time in a long period and is suitable as a capacity estimation system or an anomaly detection system mounted on the vehicle 2603.

The secondary battery not only drives the electric motor (not illustrated) but also can supply electric power to a light-emitting device such as a headlight or a room light. Furthermore, the secondary battery can supply electric power to a display device and a semiconductor device included in the vehicle 2603, such as a speedometer, a tachometer, and a navigation system.

In the vehicle 2603, the secondary batteries included in the secondary battery module 2602 can be charged by being supplied with electric power from external charging equipment by a plug-in system, a contactless power feeding system, or the like.

FIG. 13C illustrates a state in which the vehicle 2603 is supplied with electric power from ground-based charging equipment 2604 through a cable. In charging, a given method such as CHAdeMO (registered trademark) or Combined Charging System may be employed as a charging method, the standard of a connector, or the like as appropriate. For example, with a plug-in technique, the secondary battery module 2602 incorporated in the vehicle 2603 can be charged by being supplied with electric power from the outside. The charging can be performed by converting AC electric power into DC electric power through a converter, such as an AC-DC converter. The charging equipment 2604 may be provided for a house as illustrated in FIG. 13C, or may be a charging station provided in a commercial facility.

After charging with the ground-based charging equipment 2604, the capacity can be estimated with high accuracy using a learning model constructed in the charging equipment 2604 or a server capable of performing two-way communication with the charging equipment 2604. The anomaly detection system can also be constructed as described in Embodiment 1.

Although not illustrated, the vehicle may include a power receiving device so that it can be charged by being supplied with electric power from an above-ground power transmitting device in a contactless manner. In the case of the contactless power feeding system, by incorporating a power transmitting device in a road or an exterior wall, charging can be performed not only when the vehicle is stopped but also when driven. In addition, this contactless power feeding system may be utilized to transmit and receive power between vehicles. Furthermore, a solar cell may be provided in the exterior of the vehicle to charge the secondary battery while the vehicle is stopped or driven. To supply electric power in such a contactless manner, an electromagnetic induction method or a magnetic resonance method can be used.

The house illustrated in FIG. 13C includes a power storage system 2612 including a secondary battery module and a solar panel 2610. The power storage system 2612 is electrically connected to the solar panel 2610 through a wiring 2611 or the like. The power storage system 2612 may be electrically connected to the ground-based charging equipment 2604. The power storage system 2612 can be charged with electric power generated by the solar panel 2610. The secondary battery module 2602 included in the vehicle 2603 can be charged with the electric power stored in the power storage system 2612 through the charging equipment 2604.

The electric power stored in the power storage system 2612 can also be supplied to other electronic devices in the house. Thus, with the use of the power storage system 2612 as an uninterruptible power supply, electronic devices can be used even when electric power cannot be supplied from a commercial power supply due to power failure or the like.

This embodiment can be implemented in appropriate combination with any of the other embodiments.

### Example 1

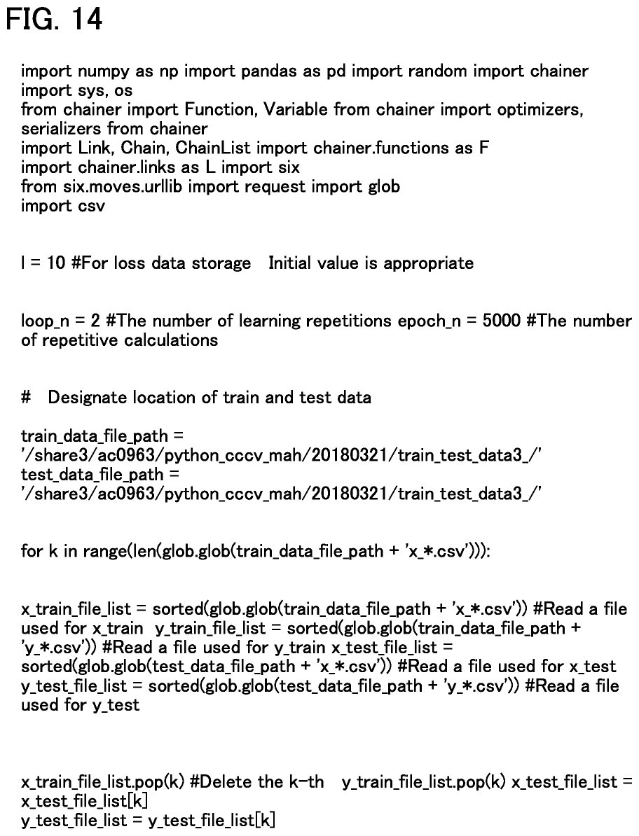

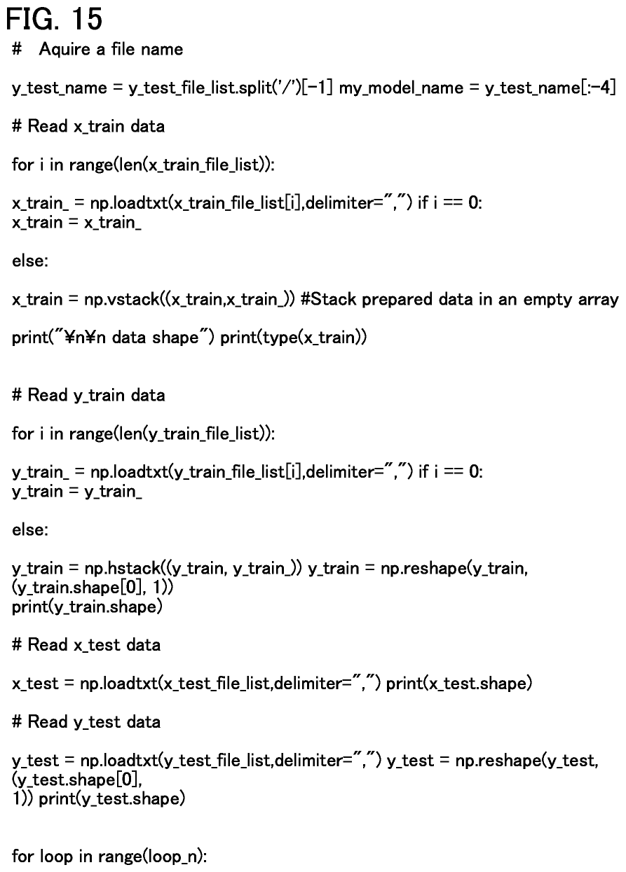

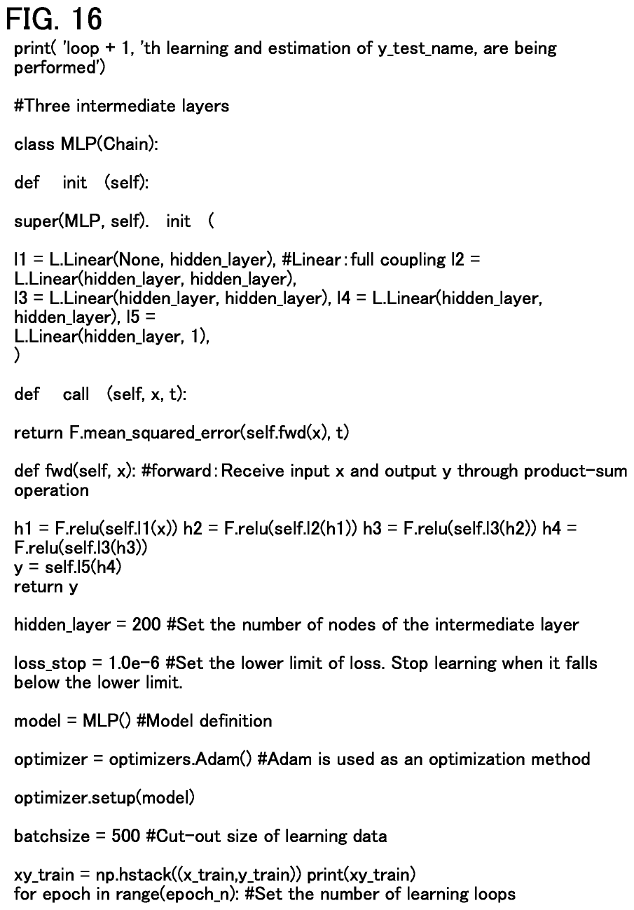

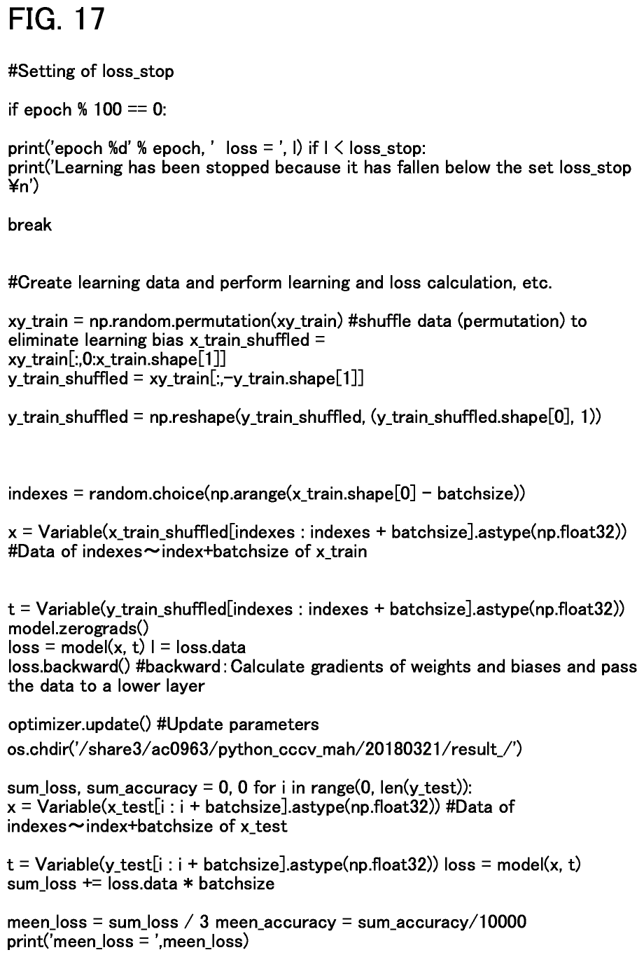

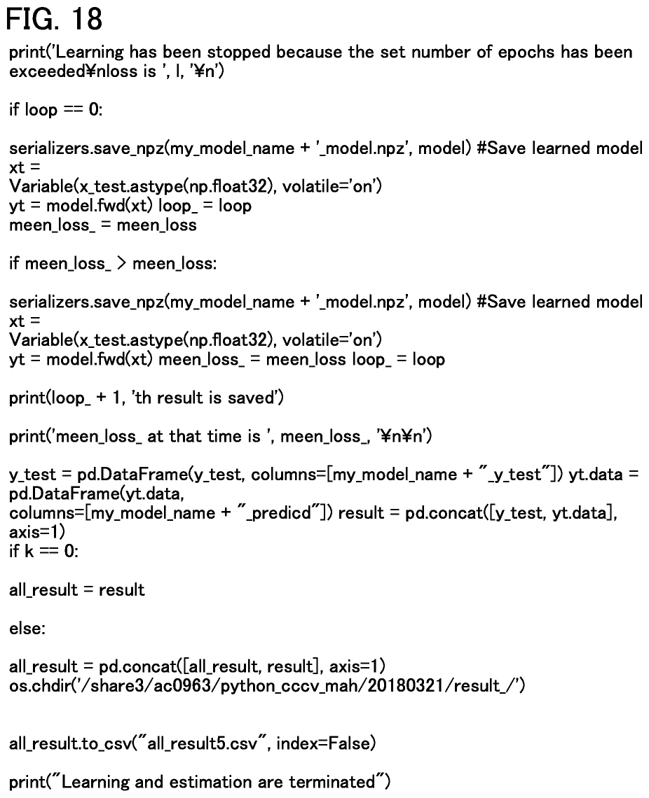

In this example, examples of programs that were actually formed are shown in FIG. 14, FIG. 15, FIG. 16, FIG. 17, and FIG. 18.

A CPU or a GPU capable of constructing a learning model uses data on a memory to access to a program (Python in this example) stored in an SSD (or a hard disk) and reads the program, the program stored in the SSD (or the hard disk) is loaded in the memory and developed on the memory as a process.

A program that constructs a learning model and a program that estimates the capacity and outputs it are shown in FIG. 14, FIG. 15, FIG. 16, FIG. 17, and FIG. 18. Note that data is referred to in the program, but only the file name is shown and the contents are omitted here because the amount of data is enormous.

For example, the deterioration of an actual vehicle battery can be predicted by transplanting models and parameters obtained by learning using the neural network to an in-vehicle ECU, specifically, a microcomputer or a microprocessor, or the like. Data for learning is obtained in advance using a secondary battery manufactured with the same manufacturing apparatus as that for the targeted secondary battery.

Even when the amount of data relating to charge and discharge of a secondary battery is large and the data is complicated, two or more parameters, which are the CC time and the CV time in this example, are keys for capacity estimation; accordingly, high accuracy of capacity estimation can be obtained with use of these parameters and the model obtained by neural network learning.

In the case where processing of capacity estimation of the secondary battery is executed by software, a program or the like can be installed from a network, a storage medium, or a computer in which a program that constructs software is incorporated in hardware. A program stored in a computer-readable storage medium such as a CD-ROM (Compact Disk Read Only Memory) is installed, and the program for capacity estimation of the secondary battery is executed. The processing by the program is not necessarily performed in order or sequentially, and may be performed in parallel, for example.

### REFERENCE NUMERALS

300: secondary battery, 301: positive electrode can, 302: negative electrode can, 303: gasket, 304: positive electrode, 305: positive electrode current collector, 306: positive electrode active material layer, 307: negative electrode, 308: negative electrode current collector, 309: negative electrode active material layer, 310: separator, 600: secondary battery, 601: positive electrode cap, 602: battery can, 603: positive electrode terminal, 604: positive electrode, 605: separator, 606: negative electrode, 607: negative electrode terminal, 608: insulating plate, 609: insulating plate, 610: gasket, 611: PTC element, 612: safety valve mechanism, 613: conductive plate, 614: conductive plate, 615: module, 616: conductive wire, 980: secondary battery, 981: film, 982: film, 993: wound body, 994: negative electrode, 995: positive electrode, 996: separator, 997: lead electrode, 998: lead electrode, 2100: mobile phone device, 2101: housing, 2102: display portion, 2103: operation button, 2104: external connection port, 2105: speaker, 2106: microphone, 2107: secondary battery module, 2200: electronic cigarette, 2201: heating element, 2202: stick, 2204: secondary battery module, 2300: unmanned aircraft, 2301: secondary battery module, 2302: rotor, 2303: camera, 2400: electric two-wheeled vehicle, 2401: secondary battery module, 2402: display portion, 2403: handle, 2500: electric bicycle, 2502: battery pack, 2601: secondary battery, 2602: secondary battery module, 2603: vehicle, 2604: charging equipment, 2610: solar panel, 2611: wiring, 2612: power storage system

1. A method of estimating a state of charge of a secondary battery, comprising:
measuring a charge inception voltage value of the secondary battery;
measuring a first time from charge inception until when terminal voltage of the secondary battery reaches a reference voltage;
measuring a second time from time when the terminal voltage reaches the reference voltage until when charge is terminated; and
calculating capacity of the secondary battery by inputting the charge inception voltage value, the first time, and the second time to a neural network unit.

2. A method of estimating a state of charge of a secondary battery, comprising:
measuring a charge inception voltage value of the secondary battery;
measuring a first time from charge inception until when terminal voltage of the secondary battery reaches a reference voltage;
measuring a second time from time when the terminal voltage reaches the reference voltage until when charge is terminated;
measuring a voltage value after a third time from charge is terminated until when a chemical reaction inside the secondary battery is stabilized; and
calculating capacity of the secondary battery by inputting the charge inception voltage value, the first time, the second time, and the voltage value to a neural network unit.

3. (canceled)

4. The method of estimating a state of charge of a secondary battery, according to claim 1, wherein the secondary battery is included in a vehicle.

5. The method of estimating a state of charge of a secondary battery, according to claim 1, wherein the neural network unit is included in an electronic control unit of a vehicle.

6. The method of estimating a state of charge of a secondary battery, according to claim 1,
wherein the secondary battery is included in a vehicle, and
wherein the calculation of the capacity of the secondary battery is performed while the vehicle is moving.

7. The method of estimating a state of charge of a secondary battery, according to claim 1, wherein the calculation of the capacity of the secondary battery is performed after the charge of the secondary battery is terminated.

8. The method of estimating a state of charge of a secondary battery, according to claim 2, wherein the secondary battery is included in a vehicle.

9. The method of estimating a state of charge of a secondary battery, according to claim 2, wherein the neural network unit is included in an electronic control unit of a vehicle.

10. The method of estimating a state of charge of a secondary battery, according to claim 2,
wherein the secondary battery is included in a vehicle, and
wherein the calculation of the capacity of the secondary battery is performed while the vehicle is moving.

11. The method of estimating a state of charge of a secondary battery, according to claim 2, wherein the calculation of the capacity of the secondary battery is performed after the charge of the secondary battery is terminated.
